(19) United States
(12) Patent Application Publication
(10) Pub. No.: US 2021/0302076 A1
(43) Pub. Date: Sep. 30, 2021

(54) SYSTEM AND METHOD FOR AN ENERGY RECOVERY CONDENSER

(71) Applicant: John Schumann, Lees Summit, MO (US)

(72) Inventor: John Schumann, Lees Summit, MO (US)

(21) Appl. No.: 17/216,513

(22) Filed: Mar. 29, 2021

Related U.S. Application Data
(60) Provisional application No. 63/001,962, filed on Mar. 30, 2020.

(51) Int. Cl. F25B 39/04; H02N 3/00

(52) U.S. Cl. CPC F25B 39/04; H02N 3/00

(57) ABSTRACT

Examples disclosed herein provide for a method and apparatus for recovering heat energy that is removed from the system during condensation in the form of electricity. A condenser unit utilizes thermoelectric generator (TEG) modules coupled to the exterior of the condenser body to generate electricity from the temperature difference of the vapor inside the unit and the fluid outside the unit. Internal baffles on the interior of the condenser body and external heat fins on the TEG modules increase the heat transfer rate. The condenser unit is modular, and thus may be installed in preexisting systems and may be fabricated in varying sizes depending on the needs of the system. The electricity generated from the condenser unit may be directed to a charge controller, and then may be converted from DC power to AC power, or stored in a battery.

### CROSS REFERENCE TO RELATED APPLICATIONS

This application claims priority to U.S. Provisional Patent Application No. 63/001,962, filed Mar. 30, 2020.

### BACKGROUND

### 1. Field of the Invention

The present invention relates to a condenser that recovers heat energy in the form of electricity.

### 2. Description of Related Art

Condensation of vapor to liquid is a unit operation that is used in processes throughout many industries. Various forms of condensers perform this operation, but standard setups and configurations such as cooling towers, forced air heat exchangers, and liquid cooled condensers release heat energy into the atmosphere, effectively wasting the energy.

Thermoelectric generator (TEG) modules, also known as Seebeck generators, can be employed to recover heat energy and convert it into electricity. Various systems have used TEG modules to recover energy that would be released into the atmosphere, such as exhaust air from an HVAC all-air system and from a vehicle radiator. Such TEG modules may be coupled directly to a condenser body to actively recover the heat energy that would be wasted while the vapor is condensing into vapor.

So as to reduce the complexity and length of the Detailed Specification, and to fully establish the state of the art in certain areas of technology, Applicant herein expressly incorporates by reference all of the following materials identified in each numbered paragraph below.

Popov, Alexander and Shcheklein, Sergey. Universal thermal power generator, options. RU 2650439C1, 9 Jan. 2017. This reference describes an invention that utilizes TEG modules to generate electricity from a heat source and cold reservoir.

Oh, Dong-Hoon. A Thermo-Electric Power Generating Heat Exchanger and Module. KR 101435669B1, 23 Dec. 2011. This reference describes a shell-and-tube heat exchanger that utilizes TEG modules to generate electricity from the temperature difference of the hot and cold fluids.

Ramadan, M., Ali, S., Bazzi, H. and Khaled, M., September 2017. New hybrid system combining TEG modules, condenser hot air and exhaust airflow of all-air HVAC systems.

<https://www.sciencedirect.com/science/article/pii/S2214157X17301077?via%3Dihub>. This reference describes an HVAC system that utilizes TEG modules to recover heat energy from exhaust in the form of electricity.

Applicant(s) believe(s) that the material incorporated above is “non-essential” in accordance with 37 CFR 1.57, because it is referred to for purposes of indicating the background of the invention or illustrating the state of the art. However, if the Examiner believes that any of the above-incorporated material constitutes “essential material” within the meaning of 37 CFR 1.57(c)(1)-(3), Applicant(s) will amend the specification to expressly recite the essential material that is incorporated by reference as allowed by the applicable rules.

### SUMMARY

The present invention provides among other things a modular condenser that recovers heat energy in the form of electricity by utilizing TEG modules. The electricity can be sent back into the system in which the condenser is a part of or stored for other use. The modular condenser may be installed in a variety of orientations to adapt to the needs of many systems.

In various embodiments, the condenser comprises a condenser body, a vapor inlet coupled to a wall of the condenser body, and thermoelectric generator (TEG) modules coupled to an exterior of the condenser body. The condenser may have an internal baffle coupled to the interior of the condenser body. Multiple external heat dissipation fins may be coupled to the TEG modules, and may be oriented so that each TEG module is coupled to one external heat dissipation fin, each TEG module is coupled to multiple external heat dissipation fins, each heat dissipation fin is coupled to multiple TEG modules, or any combination thereof. A pan coupled to the interior of the condenser body may be included and positioned so that liquid condensate flows towards a condensate drain on a wall of the condenser body. A scavenge port may be included on a wall of the condenser body. The condenser may further include a non-condensable vent on a wall of the condenser body.

In one embodiment, the condenser comprises a condenser body that is in the shape of a rectangular prism, a vapor inlet coupled to a wall of the condenser body, a flanged connection coupled to the vapor inlet and coupled to a vapor line, multiple TEG modules coupled to an exterior of the condenser body, multiple rectangular internal baffles attached to an interior of the condenser body oriented perpendicularly to a flow of vapor through the condenser body, an insulated wireway coupled to the TEG modules coupled to a wire conduit that is coupled to the condenser body, and external heat dissipation fins coupled to the TEG modules on the exterior of the condenser body that may be oriented so that each heat dissipation fin spans across multiple TEG modules. The condenser may include a condensate drain on a bottom wall of the condenser body with a pan coupled to an interior of the condenser body positioned so that condensate flows toward the condensate drain. A scavenge port and non-condensable vents may also be included on a wall of the condenser body.

The condenser may be operated by supplying vapor to the interior of the condenser body and exposing the exterior of the condenser body to a fluid that is cooler than the vapor. A charge controller may be used to harness the electricity that is generated by the TEG modules. Remaining vapor may be removed from interior of the condenser body using the scavenge port and the liquid condensate may be removed from interior of the condenser body using the condensate drain.

Aspects and applications of the invention presented here are described below in the drawings and detailed description of the invention. Unless specifically noted, it is intended that the words and phrases in the specification and the claims be given their plain, ordinary, and accustomed meaning to those of ordinary skill in the applicable arts. The inventor is fully aware that he can be his own lexicographer if desired. The inventor expressly elects, as his own lexicographers, to use only the plain and ordinary meaning of terms in the specification and claims unless he clearly states otherwise and then further, expressly sets forth the “special” definition of that term and explains how it differs from the plain and ordinary meaning. Absent such clear statements of intent to apply a “special” definition, it is the inventor's intent and desire that the simple, plain and ordinary meaning to the terms be applied to the interpretation of the specification and claims.

The inventor is also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventor is fully informed of the standards and application of the special provisions of 35 U.S.C. § 112(f). Thus, the use of the words “function,” “means” or “step” in the Detailed Description or Description of the Drawings or claims is not intended to somehow indicate a desire to invoke the special provisions of 35 U.S.C. § 112(f), to define the invention. To the contrary, if the provisions of 35 U.S.C. § 112(f) are sought to be invoked to define the inventions, the claims will specifically and expressly state the exact phrases “means for” or “step for, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventor not to invoke the provisions of 35 U.S.C. § 112(f). Moreover, even if the provisions of 35 U.S.C. § 112(f) are invoked to define the claimed inventions, it is intended that the inventions not be limited only to the specific structure, material or acts that are described in the preferred embodiments, but in addition, include any and all structures, materials or acts that perform the claimed function as described in alternative embodiments or forms of the invention, or that are well known present or later-developed, equivalent structures, material or acts for performing the claimed function.

The foregoing and other aspects, features, and advantages will be apparent to those artisans of ordinary skill in the art from the DETAILED DESCRIPTION and DRAWINGS, and from the CLAIMS.

### BRIEF DESCRIPTION OF THE SEVERAL VIEWS OF THE DRAWINGS

A more complete understanding of the present invention may be derived by referring to the detailed description when considered in connection with the following illustrative figures. In the figures, like reference numbers refer to like elements or acts throughout the figures.

FIG. 1 depicts a perspective side view of two condenser units in parallel with external heat fins omitted on the left condenser unit, and with a grid in front of the condenser units to show how multiple units may be coupled.

FIG. 2 depicts an end view of a condenser unit.

FIG. 3 depicts a side view of a condenser unit with external heat fins omitted on the right two panel columns.

FIG. 4. depicts a top view of a condenser unit.

FIG. 5. depicts a close-up view of the top of a condenser unit.

Elements and acts in the figures are illustrated for simplicity and have not necessarily been rendered according to any particular sequence or embodiment.

### DETAILED DESCRIPTION

In the following description, and for the purposes of explanation, numerous specific details are set forth in order to provide a thorough understanding of the various aspects of the invention. It will be understood, however, by those skilled in the relevant arts, that the present invention may be practiced without these specific details. In other instances, known structures and devices are shown or discussed more generally in order to avoid obscuring the invention. In many cases, a description of the operation is sufficient to enable one to implement the various forms of the invention, particularly when the operation is to be implemented in software. It should be noted that there are many different and alternative configurations, devices and technologies to which the disclosed inventions may be applied. The full scope of the inventions is not limited to the examples that are described below.

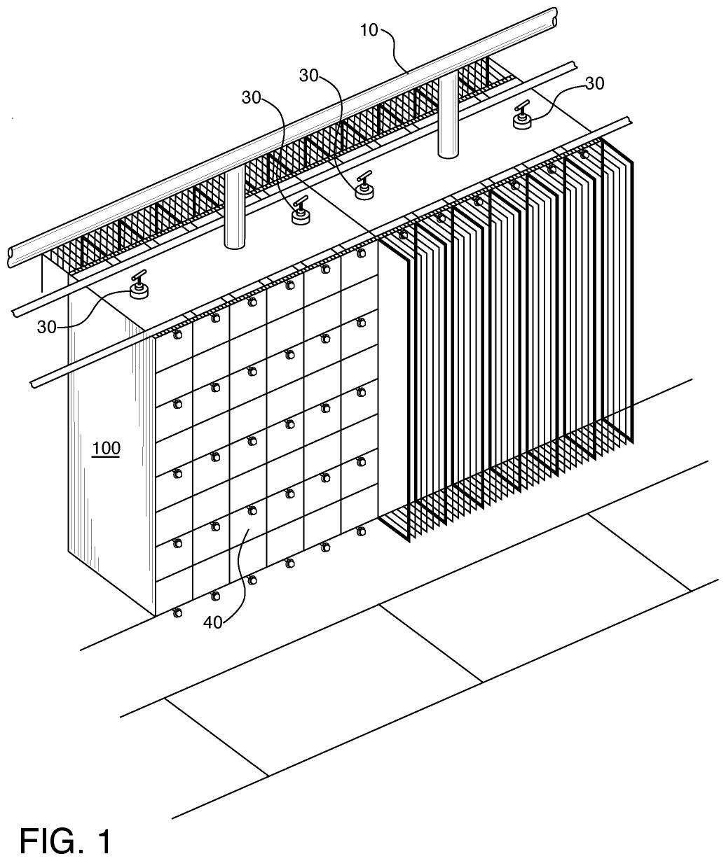

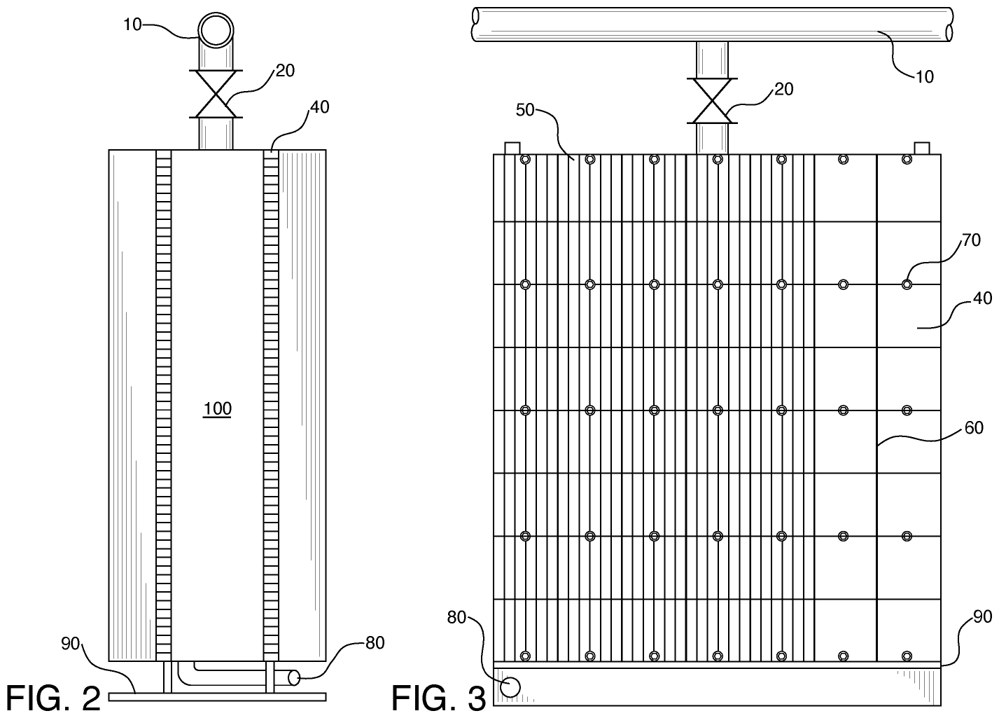

In one application, a condenser body 100 may provide an enclosure for a vapor to flow through as the vapor is condensed into liquid. In one embodiment, the condenser body 100 has a rectangular prism geometry with a hollow interior, as depicted in FIG. 1. However, other embodiments may include any geometry conducive for vapor flow and condensing vapor into liquid and may vary depending on the needs of a system. Example embodiments may include a cylindrical or triangular prism geometry. The condenser body 100 may have non-condensable vents 30 to remove any non-condensable vapors that may enter the condenser body 100. A vapor line 10 may supply vapor to a vapor inlet on the condenser body 100 using a standard connection such as a flanged connection 20. A condensate drain 80 may couple to the condenser body 100 to remove condensed liquid from the condenser body 100. A pan may be coupled to the interior of the condenser body 100 positioned so that condensed liquid flows towards the condensate drain 80. A scavenge port may also couple to the condenser body 100 to remove uncondensed vapor from the condenser body 100 depending on the needs of the system and installation. Depending on the setup of the system, a base frame 90 may be coupled to the bottom of the condenser body 100, as depicted in FIG. 2.

Internal baffles may be coupled to the interior of the condenser body 100 to increase the rate of heat transfer by increasing the surface area for heat transfer. The geometry and orientation of the internal baffles may each be optimized depending on the needs of the system. The internal baffles may be bent, shaped, or embossed as necessary to optimize heat transfer. Example embodiments of the geometry of the internal baffles may include rectangular sheets, cylindrical rods, or coils. However, other embodiments may include any geometry conducive for increasing surface area for increased heat transfer. Example embodiments of the orientation of the internal baffles may include perpendicular to the flow of vapor, parallel to the flow of vapor, or angled relative to any axis.

TEG modules 40 may be coupled to the exterior of the condenser body 100 to generate electricity from the heat that exits the system during the condensation process. In one embodiment, a bolt 70 may be used with an insulating washer to couple the TEG modules 40 to the condenser body 100, as depicted in FIG. 5. Other embodiments may include any other standard methods of coupling, such as welding or mesh retainers. The TEG modules 40 may be arranged in a grid, as depicted in FIG. 1 and FIG. 3, to maximize the surface area of heat passing through the TEG modules 40. However, other arrangements may also be used depending on the needs of the system and the geometry of the condenser body 100. The TEG modules 40 may couple to an insulated wireway 60 to direct the electricity generated by the TEG modules 40 outside of the system. The electricity may be directed to an electrical system that may convert the electricity into AC power or store the electricity in a battery. In one embodiment, the insulated wireway 60 may be arranged in a grid around the TEG modules 40, as depicted in FIG. 3. Other embodiments may use varying arrangements depending on the arrangement of the TEG panels 40 and the needs of the system.

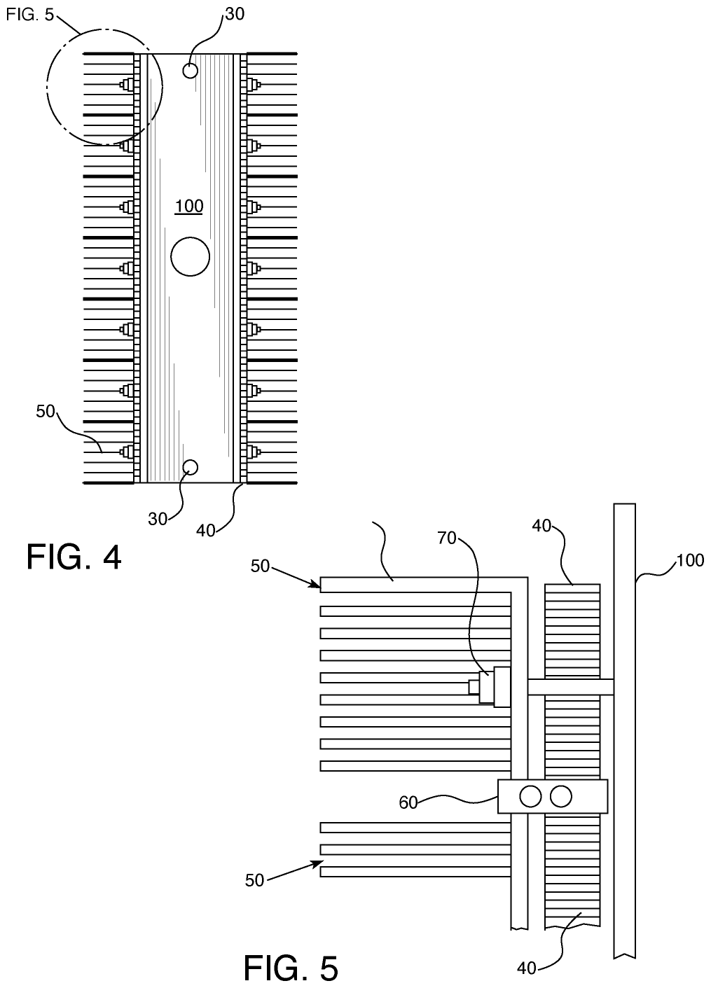

External heat dissipation fins 50 may be coupled to the TEG modules 40 to increase rate of heat transfer in the system. The geometry and orientation of the external heat fins 50 may vary depending on the geometry of the condenser body 100, the flow of a cooling fluid, and the needs of the system. The external heat dissipation fins 50 may be bent, shaped, or embossed as necessary to optimize heat transfer. In one embodiment, the external heat dissipation fins 50 may have a rectangular sheet geometry oriented perpendicularly to the TEG modules 40, as depicted in FIG. 4. Other example geometries of the external heat dissipation fins 50 may include cylindrical rods or coils. Other example orientations may include any angle extending from the TEG modules relative to any axis. The external heat dissipation fins 50 may be arranged so that one external heat dissipation fin 50 is coupled to each individual TEG module 40, one external heat dissipation fin 50 is coupled to multiple TEG modules 40, or multiple external heat dissipation fins 50 are coupled to each individual TEG module 40. Insulating material may be coupled to the exterior of condenser body 100 to prevent energy waste.

In one application, the condenser unit may be operated by coupling the vapor line 10 to the vapor inlet to allow vapor to flow into the condenser body 100. The temperature difference between the vapor and the cooling fluid causes the TEG modules 40 to generate electricity, which may be collected using the insulated wireway 60 and directed to a charge controller. In one embodiment, the cooling fluid may be naturally occurring winds. Other example embodiments may include forced air, stagnant air, or other fluid cooling systems. The condensate may flow into the condensate drain 80 and may be directed as needed by the system. Any non-condensable gas in the system may be removed from the condenser body 100 by way of the non-condensable vents 30. Any remaining condensable vapor may be removed from the condenser body 100 by way of the scavenge port, and directed to other applications as needed by the system.

The condenser unit may be installed in combination with preexisting condenser systems, other condenser units, or any combination thereof. The condenser unit may be installed in parallel, in series, stacked vertically, stacked horizontally, or any combination thereof with other preexisting condenser systems or other condenser units. The condenser unit may be installed in any physical location in the system depending on the overall setup. In one embodiment, the condenser unit may be installed on a roof to take advantage of prevailing winds. Other example embodiments may include installation near a forced air draft or a cool fluid reservoir. The base frame 90 may be installed on a swivel platform to further take advantage of prevailing winds, or on a fixed platform depending on the needs of the system. The size of the condenser unit may vary depending on the needs and limits of the system.

In the foregoing specification, the invention has been described with reference to specific exemplary embodiments. Various modifications and changes may be made, however, without departing from the scope of the present invention as set forth in the claims. The specification and figures are illustrative, not restrictive, and modifications are intended to be included within the scope of the present invention. Accordingly, the scope of the invention should be determined by the claims and their legal equivalents rather than by merely the examples described.

For example, the steps recited in any method or process claims may be executed in any order and are not limited to the specific order presented in the claims. Additionally, the components and/or elements recited in any apparatus claims may be assembled or otherwise operationally configured in a variety of permutations and are accordingly not limited to the specific configuration recited in the claims.

Benefits, other advantages, and solutions to problems have been described above with regard to particular embodiments. Any benefit, advantage, solution to problem, or any element that may cause any particular benefit, advantage, or solution to occur or to become more pronounced are not to be construed as critical, required, or essential features or components of any or all the claims.

The terms “comprise”, “comprises”, “comprising”, “having”, “including”, “includes” or any variations of such terms, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials, or components used in the practice of the present invention, in addition to those not specifically recited, may be varied or otherwise particularly adapted to specific environments, manufacturing specifications, design parameters, or other operating requirements without departing from the general principles of the same.

I claim:

1. A modular condenser that recovers energy, comprising:
a condenser body;
a vapor inlet coupled to a wall of the condenser body; and
a plurality of thermoelectric generator modules coupled to an exterior of the condenser body.

2. The condenser of claim 1, further comprising at least one baffle coupled to the interior of the condenser body.

3. The condenser of claim 1, further comprising a plurality of heat dissipation fins coupled to the plurality of thermoelectric generator modules, wherein each individual heat dissipation fin is coupled to a single thermoelectric generator module.

4. The condenser of claim 1, further comprising a plurality of heat dissipation fins coupled to the plurality of thermoelectric generator modules, wherein each individual heat dissipation fin is coupled to multiple thermoelectric generator modules.

5. The condenser of claim 1, further comprising a plurality of heat dissipation fins coupled to the plurality of thermoelectric generator modules, wherein multiple heat dissipation fins are coupled to each individual thermoelectric generator module.

6. The condenser of claim 1, further comprising an insulated wireway coupled to the thermoelectric generator module and coupled to a wire conduit that is coupled to the condenser body.

7. The condenser of claim 1, further comprising a condensate drain on a wall of the condenser body.

8. The condenser of claim 1, further comprising a pan coupled to the interior of the condenser body positioned so that condensate flows to the condensate drain.

9. The condenser of claim 1, further comprising a scavenge port on a wall of the condenser body.

10. The condenser of claim 1, further comprising at least one non-condensable vent on a wall of the condenser body.

11. A modular condenser that recovers energy, comprising:
a condenser body having a shape of a rectangular prism;
a vapor inlet coupled to the condenser body;
a plurality of thermoelectric generator modules coupled to the exterior of the condenser body;
a plurality of rectangular internal baffles coupled to an interior of the condenser body oriented perpendicularly to a flow of vapor;
a plurality of rectangular external heat fins coupled to the thermoelectric generator modules; and
an insulated wireway coupled to the thermoelectric generator modules and coupled to a wire conduit that is coupled to the condenser body.

12. The condenser of claim 11, further comprising a condensate drain on a bottom wall of the condenser body.

13. The condenser of claim 11, further comprising a pan coupled to the interior of the condenser body positioned so that condensate flows to the condensate drain.

14. The condenser of claim 11, further comprising a scavenge port on a wall of the condenser body.

15. The condenser of claim 11, further comprising at least one non-condensable vent on a wall of the condenser body.

16. The condenser of claim 11, further comprising a flange coupled to the vapor inlet.

17. A method of operating the modular condenser that recovers energy to efficiently condense vapor into liquid, the method comprising:
supplying a vapor to the vapor inlet of the condenser so that vapor flows into the condenser body; and
exposing the exterior of the condenser body to a fluid that is cooler than the vapor;

18. The method of claim 17, further comprising directing electricity that is generated by the thermoelectric generator modules to an electrical system.

19. The method of claim 17, further comprising removing the vapor from the condenser body by way of the scavenge port.

20. The method of claim 17, further comprising removing a liquid condensate from the condenser body by way of the condensate drain.
